(19) United States
(12) Patent Application Publication
(10) Pub. No.: US 2012/0321787 A1
(43) Pub. Date: Dec. 20, 2012

(54) ROTATION SYSTEM FOR THIN FILM FORMATION AND METHOD THEREOF

(76) Inventors: Cheng Chia Fang, Taipei City (TW); Cheng Chieh Yang, Taipei City (TW); Heng Liu, Sunnyvale, CA (US)

(21) Appl. No.: 13/162,431

(22) Filed: Jun. 16, 2011

(51) Int. Cl. C23C 16/458; C23C 16/46

(52) U.S. Cl. 427/255.5; 118/730; 118/725; 118/500

(57) ABSTRACT

System and method for forming one or more layers of one or more materials on one or more substrates. The system includes a rotating shell, a susceptor component supported by the rotating shell, and a driving component below the susceptor component and configured to drive the rotating shell and the susceptor component to rotate around a susceptor axis. Additionally, the system includes one or more holder gears located on the susceptor component and configured to rotate around the susceptor axis with the susceptor component and support the one or more substrates, and a central gear engaged to the one or more holder gears and configured to cause the one or more holder gears to rotate around one or more holder axes respectively if the one or more holder gears rotate around the susceptor axis. The susceptor axis is different from the one or more holder axes.

### 1. BACKGROUND OF THE INVENTION

The present invention is directed to methods and systems of material fabrication. More particularly, the invention provides a rotation system and related method for forming epitaxial layers of semiconductor materials. Merely by way of example, the invention has been applied to metal-organic chemical vapor deposition. But it would be recognized that the invention has a much broader range of applicability.

Thin film deposition has been widely used for surface processing of various objects, such as jewelry, dishware, tools, molds, and/or semiconductor devices. Often, on surfaces of metals, alloys, ceramics, and/or semiconductors, thin films of homogeneous or heterogeneous compositions are formed in order to improve wear resistance, heat resistance, and/or corrosion resistance. The techniques of thin film deposition usually are classified into at least two categories—physical vapor deposition (PVD) and chemical vapor deposition (CVD).

Depending on deposition techniques and process parameters, the deposited thin films may have a crystalline, polycrystalline or amorphous structure. The crystalline thin films often are used as epitaxial layers, which are important for fabrication of integrated circuits. For example, the epitaxial layers are made of semiconductor and doped during formation, resulting in accurate dopant profiles without being contaminated by oxygen and/or carbon impurities.

One type of chemical vapor deposition (CVD) is called metal-organic chemical vapor deposition (MOCVD). For MOCVD, one or more carrier gases can be used to carry one or more gas-phase reagents and/or precursors into a reaction chamber that contains one or more semiconductor substrates (e.g., one or more semiconductor wafers). The backside of the semiconductor substrates usually is heated through radio-frequency induction or by a resistor, in order to raise the temperature of the semiconductor substrates and their ambient temperature. At the elevated temperatures, one or more chemical reactions can occur, converting the one or more reagents and/or precursors (e.g., in gas phase) into one or more solid products that are deposited onto the surface of the semiconductor substrates.

Specifically, the epitaxial layers made by MOCVD often are used to make light-emitting diodes. The quality of these diodes is affected by various factors, such as flow stability inside the reaction chamber and/or accuracy of temperature control. These factors can significantly affect uniformity of the epitaxial layers.

Hence it is highly desirable to improve techniques for forming epitaxial layers.

### 2. BRIEF SUMMARY OF THE INVENTION

The present invention is directed to methods and systems of material fabrication. More particularly, the invention provides a rotation system and related method for forming epitaxial layers of semiconductor materials. Merely by way of example, the invention has been applied to metal-organic chemical vapor deposition. But it would be recognized that the invention has a much broader range of applicability.

According to one embodiment, a system for forming one or more layers of one or more materials on one or more substrates includes a rotating shell, a susceptor component supported by the rotating shell, and a driving component below the susceptor component and configured to drive the rotating shell and the susceptor component to rotate around a susceptor axis. Additionally, the system includes one or more holder gears located on the susceptor component and configured to rotate around the susceptor axis with the susceptor component and support the one or more substrates, and a central gear engaged to the one or more holder gears and configured to cause the one or more holder gears to rotate around one or more holder axes respectively if the one or more holder gears rotate around the susceptor axis. The susceptor axis is different from the one or more holder axes.

According to another embodiment, a system for forming one or more layers of one or more materials on one or more substrates includes a rotating shell, a susceptor component supported by the rotating shell, and a driving component below the susceptor component and configured to drive the rotating shell and the susceptor component to rotate around a susceptor axis. Additionally, the system includes one or more holder gears located on the susceptor component and configured to rotate around the susceptor axis with the susceptor component and support the one or more substrates, and a central gear engaged to the one or more holder gears and configured to cause the one or more holder gears to rotate around one or more holder axes respectively if the one or more holder gears rotate around the susceptor axis. Moreover, the system includes a showerhead component located above the susceptor component and not in direct contact with the susceptor component.

According to yet another embodiment, a method for forming one or more layers of one or more materials on one or more substrates includes driving a first gear to rotate by a motor. The first gear is engaged to a second gear. Additionally, the method includes causing the second gear to rotate around a susceptor axis by the first gear. The second gear is attached to the rotating shell. Moreover, the method includes driving the rotating shell to rotate around the susceptor axis by the second gear, and causing the susceptor component to rotate around the susceptor axis by the rotating shell. The susceptor component is configured to support one or more holder gears. Also, the method includes causing the one or more holder gears to rotate around the susceptor axis by the susceptor component. The one or more holder gears are configured to support the one or more substrates. Additionally, the method includes causing the one or more holder gears to rotate around one or more holder axes respectively by a central gear. The central gear is engaged to the one or more holder gears. The one or more holder axes are different from the susceptor axis.

Many benefits are achieved by way of the present invention over conventional techniques. According to some embodiments, a system for rotating substrate holders is used to rotate substrates. For example, the rotation of the substrates can improve uniformity of reactive gases above the substrates and also improve uniformity of thin films that are formed on the substrates. In another example, the rotation of the substrates can improve the backside heating of the substrates and improve quality of the thin films. According to certain embodiments, the system for rotating substrate holders includes a susceptor that supports the substrate holders. For example, the susceptor can cause the substrate holders to rotate around a susceptor axis. In another example, the substrate holders also rotate around holder axes respectively. In yet another example, the system for rotating substrate holders is used for thin-film deposition, such as metal-organic chemical vapor deposition.

Depending upon embodiment, one or more of these benefits may be achieved. These benefits and various additional objects, features and advantages of the present invention can be fully appreciated with reference to the detailed description and accompanying drawings that follow.

### 3. BRIEF DESCRIPTION OF THE DRAWINGS

FIGS. 1(A) and (B) are simplified diagrams showing a rotation system for forming one or more materials on one or more substrates according to an embodiment of the present invention.

FIG. 2(A) is a simplified diagram showing the rotation system with the central gear engaged to the one or more holder gears according to an embodiment of the present invention.

FIG. 2(B) is a simplified diagram showing the rotation system with the substrate holder, the holder gear, and the holder ring in an assembled condition according to an embodiment of the present invention.

FIG. 3 is a simplified diagram showing rotation of the substrate holder as part of the rotation system for forming one or more materials on one or more substrates according to an embodiment of the present invention.

FIG. 4 is a simplified diagram showing rotation of the substrate holder as part of the rotation system for forming one or more materials on one or more substrates according to another embodiment of the present invention.

FIGS. 5(A) and (B) are simplified diagrams showing a reaction system that includes the rotation system for forming one or more materials on one or more substrates according to an embodiment of the present invention.

### 4. DETAILED DESCRIPTION OF THE INVENTION

The present invention is directed to methods and systems of material fabrication. More particularly, the invention provides a rotation system and related method for forming epitaxial layers of semiconductor materials. Merely by way of example, the invention has been applied to metal-organic chemical vapor deposition. But it would be recognized that the invention has a much broader range of applicability.

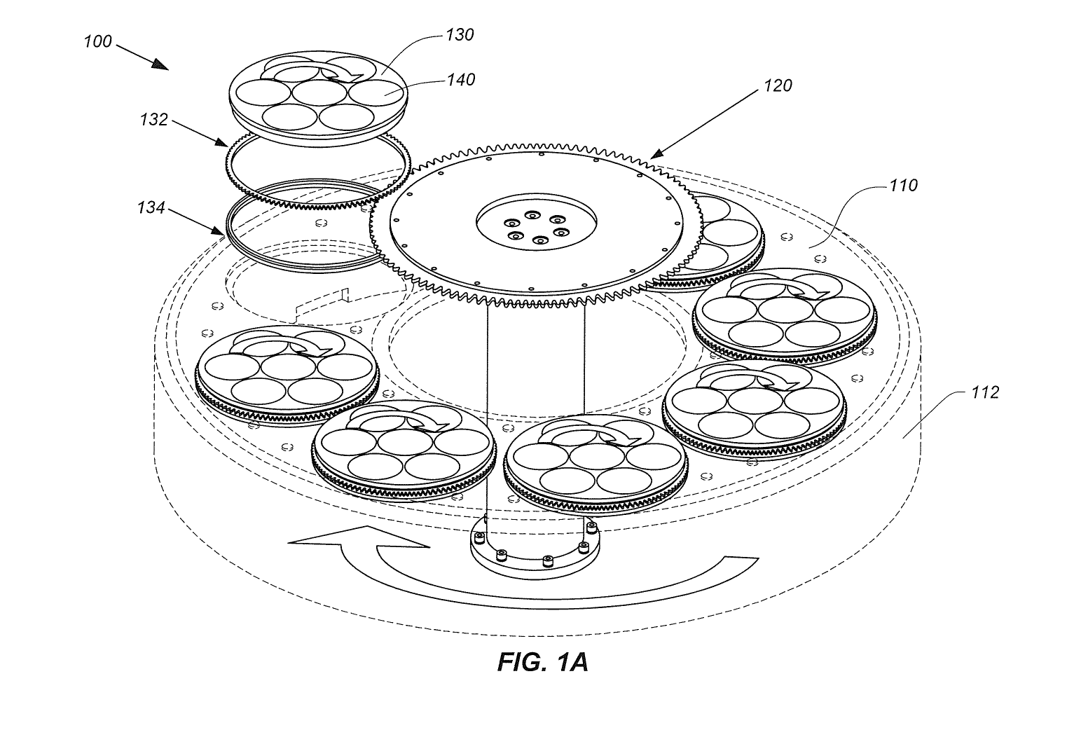

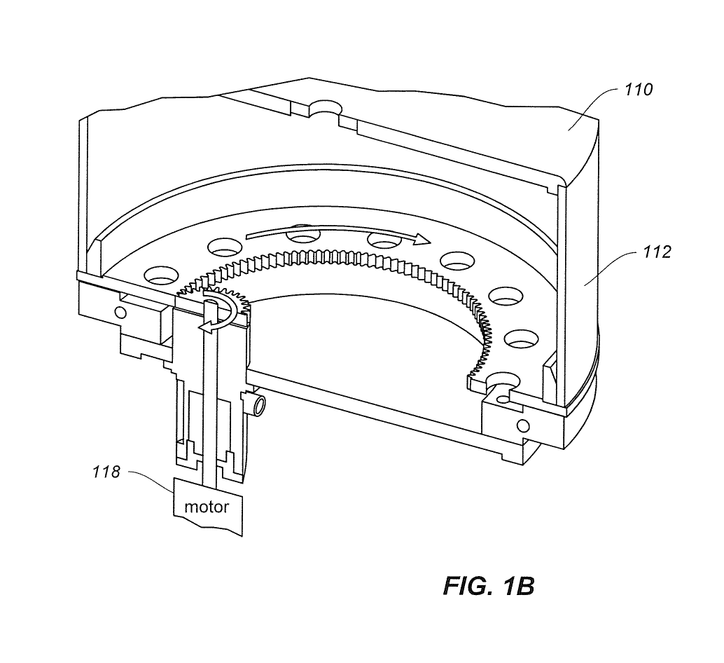

FIGS. 1(A) and (B) are simplified diagrams showing a rotation system for forming one or more materials on one or more substrates according to an embodiment of the present invention. These diagrams are merely examples, which should not unduly limit the scope of the claims. One of ordinary skill in the art would recognize many variations, alternatives, and modifications. The rotation system 100 includes a susceptor 110, a rotating shell 112, an internal gear 114, an external gear 116, and a motor 118. Additionally, the rotation system 100 includes a central gear 120. Moreover, the rotation system 100 includes one or more substrate holders 130, one or more holder gears 132, and one or more holder rings 134. For example, a substrate holder 130 is used to hold one or more substrates 140 (e.g., one or more wafers). In another example, the internal gear 114 and the external gear 116 form a driving assembly, which also includes the motor 118.

Although the above has been shown using a selected group of components for the system 100, there can be many alternatives, modifications, and variations. For example, some of the components may be expanded and/or combined. Other components may be inserted to those noted above. Depending upon the embodiment, the arrangement of components may be interchanged with others replaced.

In one embodiment, the rotating shell 112 is fixed to the internal gear 114 at the bottom, and supports, directly or indirectly, the susceptor 110 at the top. For example, the rotating shell 112 is fixed to the susceptor 110 at the top. In another example, the internal gear 114 is engaged to the external gear 116. In yet another example, the external gear 116 is driven to rotate by the motor 118, causing the internal gear 114 to also rotate. The rotation of the internal gear 114 brings the rotating shell 112 and the susceptor 110 to rotate around a common axis (e.g., a susceptor axis) according to one embodiment. For example, the rotating shell 112 can rotate using a slewing bearing. According to another embodiment, on the susceptor 110, there are the one or more substrate holders 130, the one or more holder gears 132, and the one or more holder rings 134. For example, the one or more substrate holders 130, the one or more holder gears 132, and the one or more holder rings 134 also rotate around the common axis with the susceptor 110. In another example, each of the one or more holder gears 132 supports a substrate holder 130, and each of the one or more substrate holders 130 is configured to carry one or more substrates 140 (e.g., one or more wafers).

According to some embodiments, the central gear 120 is engaged to the one or more holder gears 132. In one embodiment, the central gear 120 is stationary when the one or more holder gears 132 rotate around the common axis with the susceptor 110, causing the one or more holder gears 132 to rotate around their corresponding holder axes respectively. In another embodiment, the central gear 120 rotates around the common axis in one direction at an angular speed, when the one or more holder gears 132 rotate around the common axis with the susceptor 110 in the same direction but at a different speed, causing the one or more holder gears 132 to rotate around their corresponding holder axes respectively. For example, the angular speed of rotation by the one or more holder gears 132 around their corresponding holder axes is determined by the gear ratio between the central gear 120 and each of the one or more holder gears 132 and by the angular-speed ratio between the central gear 120 and each of the one or more holder gears 132 around the common axis. In yet another embodiment, the central gear 120 rotates around the common axis in one direction, when the one or more holder gears 132 rotate around the common axis with the susceptor 110 in another direction, causing the one or more holder gears 132 to rotate around their corresponding holder axes respectively.

According to certain embodiments, the one or more holder gears 132 are fixed with the one or more substrate holders 130, bringing the one or more substrate holders 130 to also rotate around their corresponding holder axes respectively. According to some embodiments, the one or more holder gears 132 are in contact with the one or more holder rings 134 through one or more ball bearings respectively. For example, the one or more holder rings 134 are fixed with the susceptor 110, so they do not rotate around the holder axes with the one or more holder gears 132 respectively.

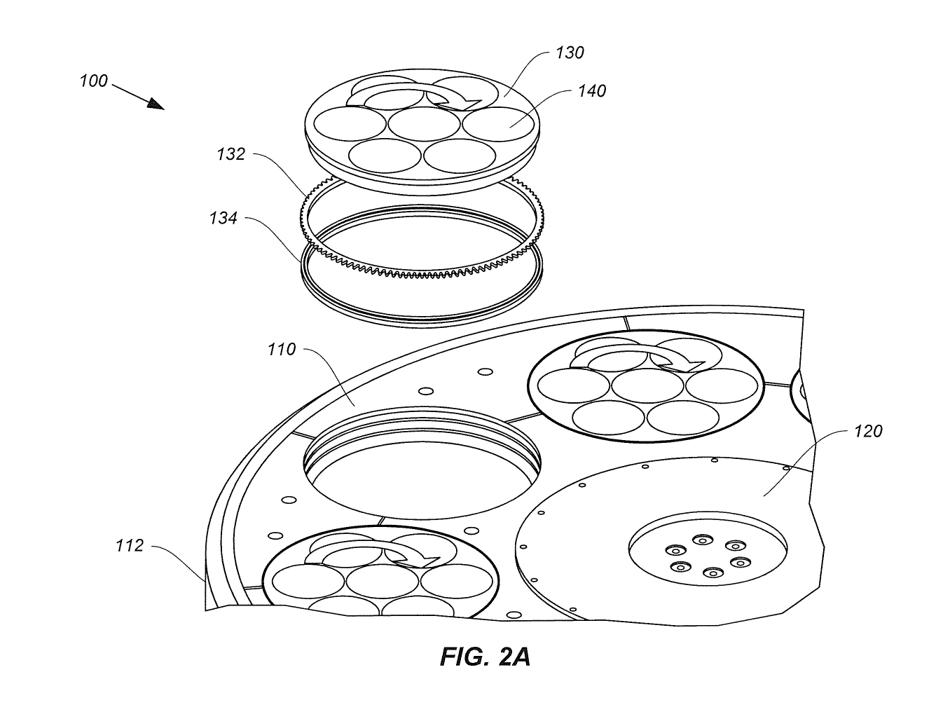

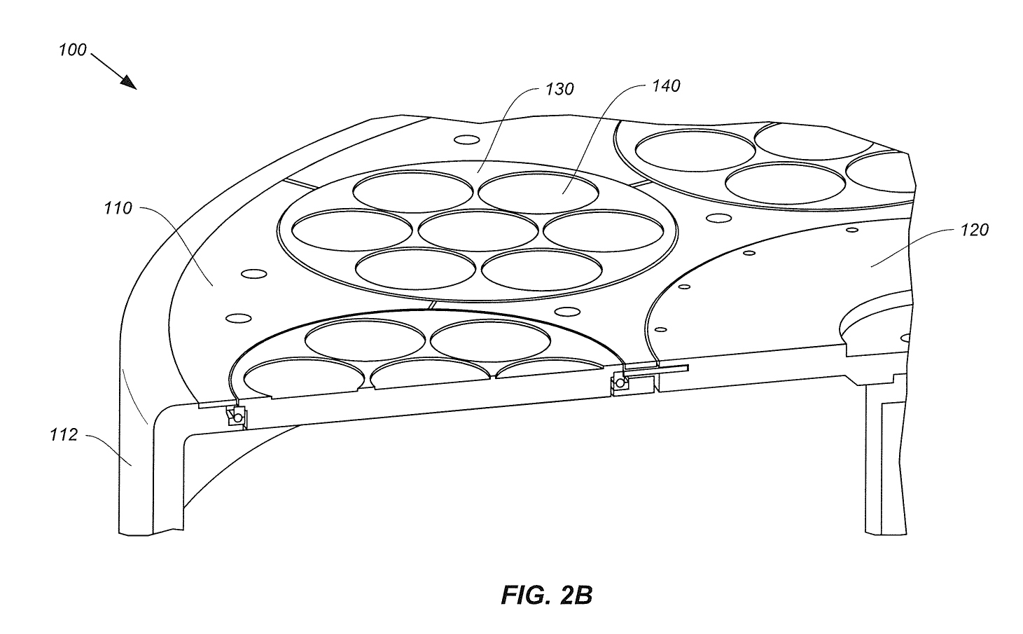

As shown in FIG. 1(A), a substrate holder 130, a holder gear 132, and a holder ring 134 are shown in a disassembled condition and the central gear 120 is shown detached from the one or more holder gears 132, in order to clearly depict these components. FIG. 2(A) is a simplified diagram showing the rotation system 100 with the central gear 120 engaged to the one or more holder gears 132 according to an embodiment of the present invention. Additionally, FIG. 2(B) is a simplified diagram showing the rotation system 100 with the substrate holder 130, the holder gear 132, and the holder ring 134 in an assembled condition according to an embodiment of the present invention. These diagrams are merely examples, which should not unduly limit the scope of the claims. One of ordinary skill in the art would recognize many variations, alternatives, and modifications.

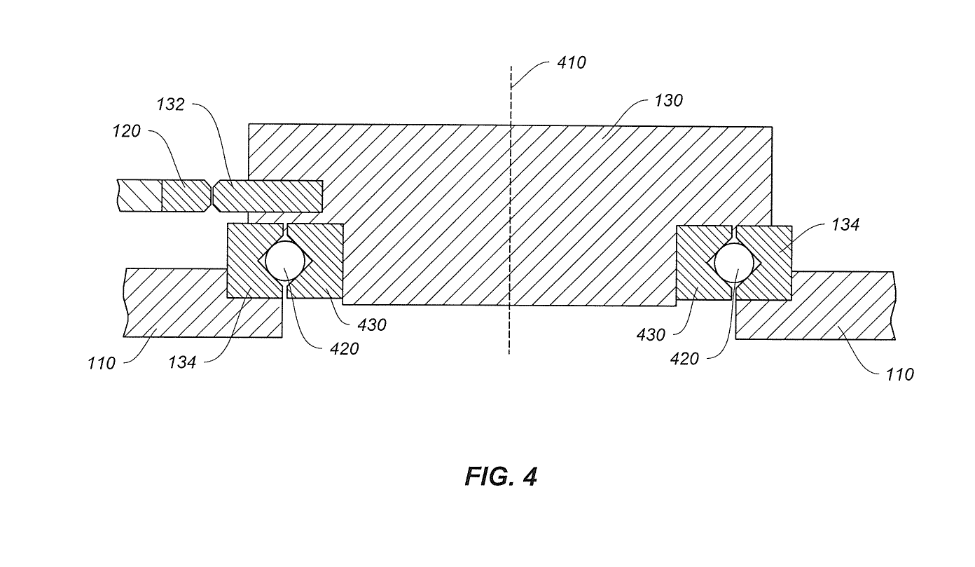

As discussed above and further emphasized here, FIGS. 1(A), 1(B), 2(A), and 2(B) are merely examples, which should not unduly limit the scope of the claims. One of ordinary skill in the art would recognize many variations, alternatives, and modifications. For example, the one or more substrate holders 130 are removed, so that each of the one or more holder gears 132 is configured to directly support the one or more substrates 140 (e.g., one or more wafers), and the one or more substrates 140 rotate with the corresponding holder gear 132 around the common axis and/or around the corresponding holder axis. In another example, the one or more holder rings 134 are removed as shown in FIG. 4.

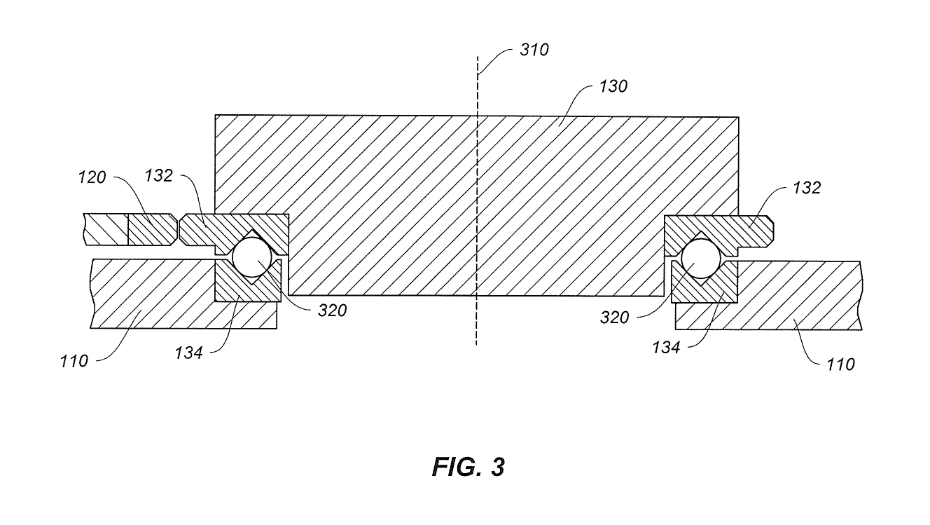

FIG. 3 is a simplified diagram showing rotation of the substrate holder 130 as part of the rotation system 100 for forming one or more materials on one or more substrates according to an embodiment of the present invention. This diagram is merely an example, which should not unduly limit the scope of the claims. One of ordinary skill in the art would recognize many variations, alternatives, and modifications.

As shown in FIG. 3, each of the one or more holder gears 132 forms a hollow ring which is used to support its corresponding substrate holder 130. For example, each of the one or more holder gears 132 and its corresponding substrate holder 130 rotate around a holder axis 310 using a ball bearing 320. In another example, the ball bearing 320 is located between a bottom grove of the holder gear 132 and a top grove of the holder ring 134. In yet another example, the holder ring 134 is fixed to the susceptor 110.

FIG. 4 is a simplified diagram showing rotation of the substrate holder 130 as part of the rotation system 100 for forming one or more materials on one or more substrates according to another embodiment of the present invention. This diagram is merely an example, which should not unduly limit the scope of the claims. One of ordinary skill in the art would recognize many variations, alternatives, and modifications.

As shown in FIG. 4, each of the one or more holder gears 132 forms a hollow ring which is used to support its corresponding substrate holder 130. For example, each of the one or more holder gears 132 and its corresponding substrate holder 130 rotate around a holder axis 410 using a ball bearing 420. In another example, the ball bearing 420 is located between grooves of an inner ring 430 and a holder ring 134. For example, the inner ring 430 is fixed to the substrate holder 130.

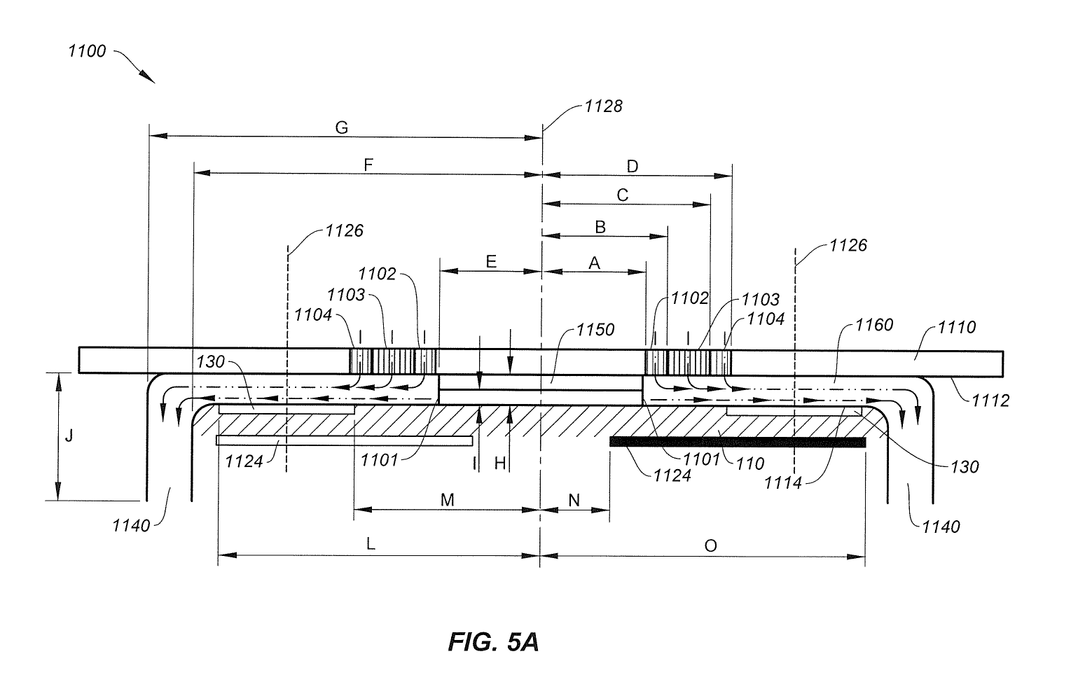

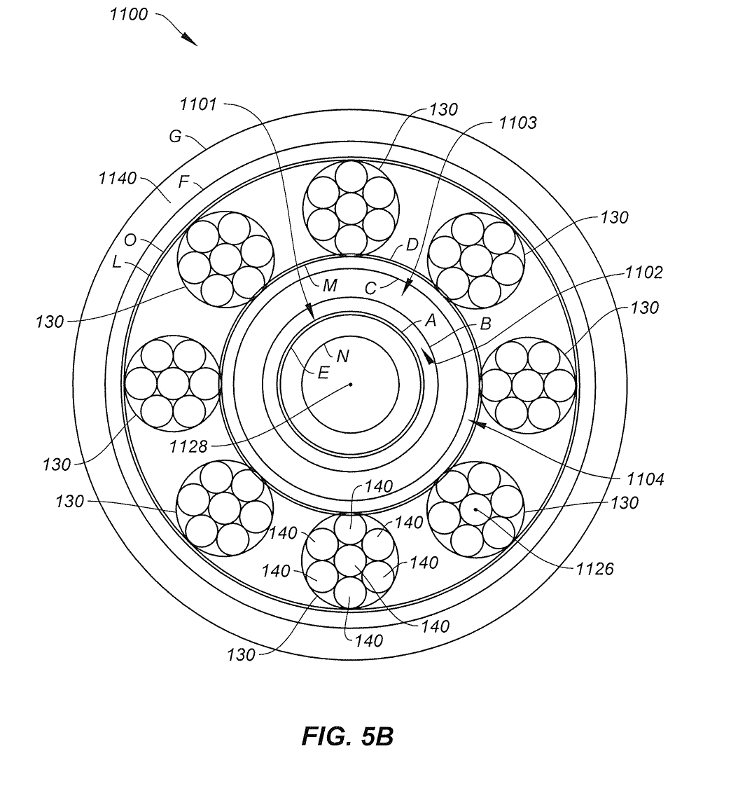

FIGS. 5(A) and (B) are simplified diagrams showing a reaction system that includes the rotation system 100 for forming one or more materials on one or more substrates according to an embodiment of the present invention. These diagrams are merely examples, which should not unduly limit the scope of the claims. One of ordinary skill in the art would recognize many variations, alternatives, and modifications.

For example, FIG. 5(A) shows a side view of the reaction system 1100, and FIG. 5(B) shows a planar view of the reaction system 1100. In another example, the reaction system 1100 includes a showerhead component 1110, the susceptor 110, inlets 1101, 1102, 1103 and 1104, one or more substrate holders 130, one or more heating devices 1124, an outlet 1140, and a central component 1150. In yet another example, the central component 1150, the showerhead component 1110, the susceptor 110, and the one or more substrate holders 130 (e.g., located on the susceptor 110) form a reaction chamber 1160 with the inlets 1101, 1102, 1103 and 1104 and the outlet 1140. In yet another example, the one or more substrate holders 130 each are used to carry one or more substrates 140 (e.g., one or more wafers).

Although the above has been shown using a selected group of components for the system 1100, there can be many alternatives, modifications, and variations. For example, some of the components may be expanded and/or combined. Other components may be inserted to those noted above. Depending upon the embodiment, the arrangement of components may be interchanged with others replaced.

According to one embodiment, the inlet 1101 is formed within the central component 1150 and configured to provide one or more gases in a direction that is substantially parallel to a surface 1112 of the showerhead component 1110. For example, the central component 1150 is located above (e.g., on) the central gear 120. In another example, the one or more gases flows (e.g., flows up) into the reaction chamber 1160 near the center of the reaction chamber 1160 and then flows through the inlet 1101 outward radially, away from the center of the reaction chamber 1160. According to another embodiment, the inlets 1102, 1103 and 1104 are formed within the showerhead component 1110 and configured to provide one or more gases in a direction that is substantially perpendicular to the surface 1112.

For example, various kinds of gases are provided through the inlets 1101, 1102, 1103 and 1104 as shown in Table 1.

TABLE 1

| Inlets | 1101 | 1102 | 1103 | 1104 |
|---|---|---|---|---|
| Gases | NH₃ | N₂, H₂, and/or | N₂, H₂, and/or | N₂, H₂, and/or |
| | | TMG | NH₃ | TMG |

In one embodiment, the susceptor 110 is configured to rotate around a susceptor axis 1128 (e.g., a central axis), and each of the one or more substrate holders 130 is configured to rotate around a corresponding holder axis 1126 (e.g., the holder axis 310 or 410). In another embodiment, the one or more substrate holders 130 can rotate, with the susceptor 110, around the susceptor axis 1128, and also rotate around their corresponding holder axes 1126. For example, the one or more substrates 140 on the same substrate holder 130 can rotate around the same holder axis 1126.

According to one embodiment, the inlets 1101, 1102, 1103 and 1104, and the outlet 1140 each have a circular configuration around the susceptor axis 1128. According to another embodiment, the one or more substrate holders 130 (e.g., eight substrate holders 130) are arranged around the susceptor axis 1128. For example, each of the one or more substrate holders 130 can carry several substrates 140 (e.g., seven substrates 140).

As shown in FIGS. 5(A) and (B), symbols A, B, C, D, E, F, G, H, I, J, L, M, N, and O represent various dimensions of the reaction system 1100 according to some embodiments. In one embodiment,
(1) A represents the distance between the susceptor axis 1128 and the inner edge of the inlet 1102;
(2) B represents the distance between the susceptor axis 1128 and the inner edge of the inlet 1103;
(3) C represents the distance between the susceptor axis 1128 and the inner edge of the inlet 1104;
(4) D represents the distance between the susceptor axis 1128 and the outer edge of the inlet 1104;
(5) E represents the distance between the susceptor axis 1128 and the inlet 1101;
(6) F represents the distance between the susceptor axis 1128 and the inner edge of the outlet 1140;
(7) G represents the distance between the susceptor axis 1128 and the outer edge of the outlet 1140;
(8) H represents the distance between the surface 1112 of the showerhead component 1110 and a surface 1114 of the susceptor 110;
(9) I represents the height of the inlet 1101;
(10) J represents the distance between the surface 1112 of the showerhead component 1110 and the outlet 1140;
(11) L represents the distance between the susceptor axis 1128 and one or more outer edges of the one or more substrate holders 130 respectively;
(12) M represents the distance between the susceptor axis 1128 and one or more inner edges of the one or more substrate holders 130 respectively;
(14) N represents the distance between the susceptor axis 1128 and one or more inner edges of the one or more heating devices 1124 respectively; and
(15) O represents the distance between the susceptor axis 1128 and one or more outer edges of the one or more heating devices 1124 respectively.

For example, L minus M is the diameter of the one or more substrate holders 130. In another example, the vertical size of the reaction chamber 1160 (e.g., represented by H) is equal to or less than 20 mm, or is equal to or less than 15 mm. In yet another example, the vertical size of the inlet 1101 (e.g., represented by I) is less than the vertical distance between the surface 1112 of the showerhead component 1110 and the surface 1114 of the susceptor 110 (e.g., represented by H). In yet another example, some magnitudes of these dimensions are shown in Table 2 below.

TABLE 2

| Dimension Symbol | Dimension Magnitude (unit: mm) |
|---|---|
| A | 105 |
| B | 120 |
| C | 150 |
| D | 165 |
| E | 100 |
| F | 330 |
| G | 415 |
| H | 10 |
| I | 5 |
| J | 150 |
| L | 310 |
| M | 145 |
| N | 96 |
| O | 320 |

In one embodiment, the one or more substrate holders 130 are located on the susceptor 110. In another embodiment, the one or more heating devices 1124 are located under the one or more substrate holders 130 respectively. For example, the one or more heating devices 1124 extend toward the center of the reaction chamber 1160 beyond the one or more substrate holders 130 respectively. In another example, the one or more heating devices 1124 preheat the one or more gases from the inlets 1101, 1102, 1103, and/or 1104 before the one or more gases reach the one or more substrate holders 130.

As discussed above and further emphasized here, FIGS. 5(A) and (B) are merely examples, which should not unduly limit the scope of the claims. One of ordinary skill in the art would recognize many variations, alternatives, and modifications. For example, the inlet 1102 is replaced by a plurality of inlets, and/or the inlet 1104 is replaced by another plurality of inlets. In another example, the inlet 1102 is formed within the central component 1150 and configured to provide one or more gases in a direction that is substantially parallel to the surface 1112 of the showerhead component 1110.

According to another embodiment, a system for forming one or more layers of one or more materials on one or more substrates includes a rotating shell, a susceptor component supported by the rotating shell, and a driving component below the susceptor component and configured to drive the rotating shell and the susceptor component to rotate around a susceptor axis. Additionally, the system includes one or more holder gears located on the susceptor component and configured to rotate around the susceptor axis with the susceptor component and support the one or more substrates, and a central gear engaged to the one or more holder gears and configured to cause the one or more holder gears to rotate around one or more holder axes respectively if the one or more holder gears rotate around the susceptor axis. The susceptor axis is different from the one or more holder axes. For example, the system is implemented according to at least FIG. 1(A), FIG. 1(B), FIG. 2(A), and/or FIG. 2(B).

According to yet another embodiment, a system for forming one or more layers of one or more materials on one or more substrates includes a rotating shell, a susceptor component supported by the rotating shell, and a driving component below the susceptor component and configured to drive the rotating shell and the susceptor component to rotate around a susceptor axis. Additionally, the system includes one or more holder gears located on the susceptor component and configured to rotate around the susceptor axis with the susceptor component and support the one or more substrates, and a central gear engaged to the one or more holder gears and configured to cause the one or more holder gears to rotate around one or more holder axes respectively if the one or more holder gears rotate around the susceptor axis. Moreover, the system includes a showerhead component located above the susceptor component and not in direct contact with the susceptor component. For example, the system is implemented according to at least FIG. 1(A), FIG. 1(B), FIG. 2(A), FIG. 2(B), FIG. 5(A), and/or FIG. 5(B).

According to yet another embodiment, a method for forming one or more layers of one or more materials on one or more substrates includes driving a first gear to rotate by a motor. The first gear is engaged to a second gear. Additionally, the method includes causing the second gear to rotate around a susceptor axis by the first gear. The second gear is attached to the rotating shell. Moreover, the method includes driving the rotating shell to rotate around the susceptor axis by the second gear, and causing the susceptor component to rotate around the susceptor axis by the rotating shell. The susceptor component is configured to support one or more holder gears. Also, the method includes causing the one or more holder gears to rotate around the susceptor axis by the susceptor component. The one or more holder gears are configured to support the one or more substrates. Additionally, the method includes causing the one or more holder gears to rotate around one or more holder axes respectively by a central gear. The central gear is engaged to the one or more holder gears. The one or more holder axes are different from the susceptor axis. For example, the system is implemented according to at least FIG. 1(A) and/or FIG. 1(B).

Although specific embodiments of the present invention have been described, it will be understood by those of skill in the art that there are other embodiments that are equivalent to the described embodiments. For example, various embodiments and/or examples of the present invention can be combined. Accordingly, it is to be understood that the invention is not to be limited by the specific illustrated embodiments, but only by the scope of the appended claims.

What is claimed is:

1. A system for forming one or more layers of one or more materials on one or more substrates, the system comprising:
a rotating shell;
a susceptor component supported by the rotating shell;
a driving component below the susceptor component and configured to drive the rotating shell and the susceptor component to rotate around a susceptor axis;
one or more holder gears located on the susceptor component and configured to rotate around the susceptor axis with the susceptor component and support the one or more substrates; and
a central gear engaged to the one or more holder gears and configured to cause the one or more holder gears to rotate around one or more holder axes respectively if the one or more holder gears rotate around the susceptor axis;
wherein the susceptor axis is different from the one or more holder axes.

2. The system of claim 1, and further comprising:
one or more substrate holders attached to the one or more holder gears respectively and configured to rotate around the susceptor axis with the one or more holder gears;
wherein:
the one or more holder gears are further configured to support the one or more substrates through the one or more substrate holders; and
the one or more substrate holders are further configured to carry the one or more substrates.

3. The system of claim 2 wherein the central gear is further configured to cause the one or more substrate holders to rotate, with the one or more holder gears, around the one or more holder axes respectively, if the one or more holder gears rotate around the susceptor axis.

4. The system of claim 2 wherein each of the one or more holder gears is configured to form a hollow ring to support a corresponding substrate holder, the corresponding substrate holder being selected from the one or more substrate holders.

5. The system of claim 1 wherein the central gear is further configured not to rotate around the susceptor axis if the one or more holder gears rotate around the susceptor axis.

6. The system of claim 1 wherein the central gear is further configured to rotate around the susceptor axis in a first direction and at a first angular speed if the one or more holder gears rotate around the susceptor axis in a second direction and at a second angular speed.

7. The system of claim 6 wherein:
the first direction and the second direction are different; and
the first angular speed and the second angular speed are different.

8. The system of claim 1 wherein the driving component includes:
a first gear located below the susceptor component and attached to the rotating shell; and
a second gear engaged to the first gear and configured to cause the first gear to rotate around the susceptor axis.

9. The system of claim 8, and further comprising a motor configured to drive the second gear to rotate in order to cause the first gear to rotate around the susceptor axis.

10. The system of claim 1, and further comprising one or more ball bearings configured to support the one or more holder gears and allow the one or more holder gears to rotate around the one or more holder axes respectively.

11. The system of claim 10, and further comprising one or more holder rings attached to the susceptor component and located between the susceptor component and the one or more holder gears respectively.

12. The system of claim 11 wherein:
each of the one or more ball bearings is located between a first groove of one corresponding holder ring and a second groove of one corresponding holder gear;
the corresponding holder ring is selected from the one or more holder rings;
the corresponding holder gear is selected from the one or more holder gears; and
the first groove is located below the second groove.

13. The system of claim 10, and further comprising:
one or more substrate holders attached to the one or more holder gears respectively and configured to rotate around the susceptor axis with the one or more holder gears and carry the one or more substrates;
one or more outer rings attached to the susceptor component; and
one or more inner rings attached to the one or more substrate holders respectively.

14. The system of claim 13 wherein:
each of the one or more ball bearings is located between an outer groove of one corresponding outer ring and an inner groove of one corresponding inner ring;
the corresponding outer ring is selected from the one or more outer rings; and
the corresponding inner ring is selected from the one or more inner rings.

15. The system of claim 14 wherein the one or more inner rings are not in direct contact with the one or more holder gears.

16. A system for forming one or more layers of one or more materials on one or more substrates, the system comprising:
a rotating shell;
a susceptor component supported by the rotating shell;
a driving component below the susceptor component and configured to drive the rotating shell and the susceptor component to rotate around a susceptor axis;
one or more holder gears located on the susceptor component and configured to rotate around the susceptor axis with the susceptor component and support the one or more substrates;
a central gear engaged to the one or more holder gears and configured to cause the one or more holder gears to rotate around one or more holder axes respectively if the one or more holder gears rotate around the susceptor axis; and
a showerhead component located above the susceptor component, not in direct contact with the susceptor component.

17. The system of claim 16, and further comprising one or more inlets configured to provide one or more gases.

18. The system of claim 17 wherein the one or more gases include ammonia and a metal-organic gas.

19. The system of claim 18 wherein the metal-organic gas is selected from a group consisting of TMG, TMA and TMI.

20. The system of claim 16 is further configured to perform chemical vapor deposition for forming the one or more layers of the one or more materials on the one or more substrates.

21. The system of claim 20 wherein the one or more materials include a Group-III nitride material.

22. The system of claim 21 wherein the Group-III nitride material is selected from a group consisting of aluminum nitride, gallium nitride, and indium nitride.

23. The system of claim 16, and further comprising a central component located above the central gear.

24. The system of claim 23, and further comprising a reaction chamber formed by at least the central component, the showerhead component, and the susceptor component.

25. The system of claim 16, and further comprising one or more substrate holders attached to the one or more holder gears respectively and configured to rotate around the susceptor axis with the one or more holder gears and to carry the one or more substrates.

26. The system of claim 25, and further comprising:
a central component located above the central gear; and
one or more heating devices located below the one or more substrate holders respectively and extended closer to the central component than the one or more substrate holders respectively.

27. A method for forming one or more layers of one or more materials on one or more substrates, the method comprising:
driving a first gear to rotate by a motor, the first gear engaged to a second gear;
causing the second gear to rotate around a susceptor axis by the first gear, the second gear attached to the rotating shell;
driving the rotating shell to rotate around the susceptor axis by the second gear;
causing the susceptor component to rotate around the susceptor axis by the rotating shell, the susceptor component being configured to support one or more holder gears;
causing the one or more holder gears to rotate around the susceptor axis by the susceptor component, the one or more holder gears being configured to support the one or more substrates; and
causing the one or more holder gears to rotate around one or more holder axes respectively by a central gear, the central gear being engaged to the one or more holder gears;
wherein the one or more holder axes are different from the susceptor axis.
